(19) United States
(12) Patent Application Publication
(10) Pub. No.: US 2017/0347490 A1
(43) Pub. Date: Nov. 30, 2017

(54) HIGH-FREQUENCY ANTENNA STRUCTURE WITH HIGH THERMAL CONDUCTIVITY AND HIGH SURFACE AREA

(71) Applicants: Texas Instruments Incorporated, Dallas, TX (US); Texas Instruments Deutschland GmbH, Freising (DE)

(72) Inventors: Matthew David Romig, Wylie, TX (US); Robert Clair Keller, Friedrichshafen (DE); Ming Li, Plano, TX (US); Yiqi Tang, Allen, TX (US)

(21) Appl. No.: 15/162,888

(22) Filed: May 24, 2016

(51) Int. Cl. H05K 7/20; H05K 1/02; H05K 13/00

(52) U.S. Cl. CPC H05K 7/20418; H05K 13/0023; H05K 1/0204; H05K 2201/066

(57) ABSTRACT

A heat dissipating antenna comprised of a low-attenuating heat spreader bonded to a high frequency antenna or antenna array.

An integrated circuit with a wireless integrated circuit chip, and a heat dissipating antenna coupled to the wireless integrated circuit chip. A method of forming a heat dissipating antenna.

### FIELD

This invention relates to an antenna for high-frequency, wireless electronic circuits. More particularly, this invention relates a heat dissipating antenna that facilitates heat removal from high-frequency electronic circuits with antennas such as those used for mobile applications.

### BACKGROUND

The power density of high-frequency integrated circuits such as are used in baseband, radio frequency, and power amplifiers is increasing as the geometries in high-frequency integrated circuits such as are used for wireless applications are scaled smaller and smaller. The increased power density results in increased thermal density requiring the attachment of heat spreaders to the wireless chips to dissipate the heat in order to keep the wireless chips operating within a safe thermal range.

Some wireless chips like those used in mobile applications such as 5G wireless communication may generate significant amounts of heat during operation and require the attachment of heat spreaders to dissipate the heat. However, an antenna array may also need to be attached to the wireless chips to broadcast and receive the wireless signals. These antenna arrays may block area to which heat spreaders (heat sinks) may be attached.

In FIG. 1A, an antenna array 112 overlies wireless integrated circuit chips 114. The antenna array 112 typically blocks heat sinks from being attached to the top side of the wireless integrated circuit chips 114.

A magnified cross sectional view of a high frequency integrated circuit 100 with an overlying antenna array 112 is shown in FIG. 1B. Wireless chips, 104 and 108, and other high-frequency components, 106, and 110, are attached to a substrate 102 such as an integrated circuit board. The antenna array 112 overlies the high-frequency integrated circuit components, 104, 106, 108, and 110. The wireless integrated chips, 104 and 108, which may be high frequency chips such as a baseband chip or an RF chip may generate significant heat during operation to power the antenna array 112 with high-frequency signals (gigahertz range).

When a conventional heat spreader 120 (FIG. C) is attached directly to the antenna array 112, the gain (strength of high-frequency wireless signals transmitted from or detected by) of the antenna is severely degraded. A parallel fin copper heat spreader 120 bonded directly to the antenna array 112 reduced the antenna gain by more than 50%. (from about 16 dB to about 7.6 dB at a frequency of 32 GHz).

For this reason, as is illustrated in FIG. 1C, heat spreaders 120 are typically attached only to the backside of the substrate 102 and are not attached to the directly to antenna 112 on the topside.

### SUMMARY

A heat dissipating antenna is comprised of a low-attenuating heat spreader bonded to a high frequency antenna or antenna array.

An integrated circuit is comprised of a wireless integrated circuit chip, and a heat dissipating antenna coupled to the wireless integrated circuit chip.

A heat dissipating antenna is formed by forming a low-attenuating heat spreader from dielectric material with high thermal conductivity and bonding it to a high frequency antenna.

### DESCRIPTION OF THE VIEWS OF THE DRAWINGS

FIG. 1A (Prior art) is a plan view of an antenna array coupled to high frequency integrated circuits.

FIG. 1B (Prior art) is a cross-section of an antenna array coupled to high frequency integrated circuits.

FIG. 1C (Prior art) is a cross-section of an antenna array with a conventional heat spreader coupled to the substrate.

FIG. 2A through 2C are illustrative examples of low-attenuating heat spreader designs

FIG. 3A through 3C are illustrative examples of heat dissipating antenna designs.

FIG. 4 is a cross-section of a heat dissipating antenna coupled to the topside of a high frequency integrated circuit chip and a conventional heat spreader coupled to the substrate.

FIG. 5 is a cross-section of a heat dissipating antenna coupled to the topside of a high frequency integrated circuit chip and a low-attenuating heat spreader coupled to the substrate.

FIG. 6 is a flow chart describing the steps in the formation of a high frequency antenna with a low-attenuation heat spreader according to embodiments.

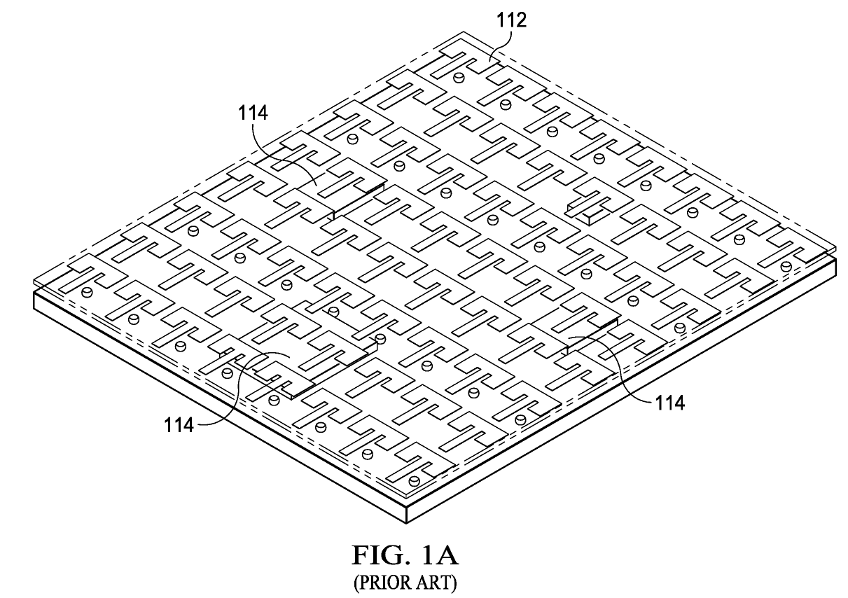

### DETAILED DESCRIPTION OF EXAMPLE EMBODIMENTS

Embodiments of the invention are described with reference to the attached figures. The figures are not drawn to scale and they are provided merely to illustrate the invention. Several aspects of the embodiments are described below with reference to example applications for illustration. It should be understood that numerous specific details, relationships, and methods are set forth to provide an understanding of the invention. One skilled in the relevant art, however, will readily recognize that the invention can be practiced without one or more of the specific details or with other methods. In other instances, well-known structures or operations are not shown in detail to avoid obscuring the invention. The embodiments are not limited by the illustrated ordering of acts or events, as some acts may occur in different orders and/or concurrently with other acts or events. Furthermore, not all illustrated acts or events are required to implement a methodology in accordance with the present invention.

The inventors have formed a high frequency antenna with high gain and with high heat dissipation. The inventors discovered that low-attenuating heat spreaders may be created by using dielectric materials with high thermal conductivity. These low-attenuating heat spreaders may be bonded to high frequency antennas or high frequency antenna arrays to form heat dissipating antennas with high gain.

Dielectric materials with high thermal conductivity such as aluminum nitride (AlN), aluminum oxide (Al₂O₃) and beryllium oxide (BeO) may be formed into a heat spreader that only slightly attenuates antenna gain. Table 1 is a list of aluminum plus several dielectric materials along with their thermal conductivity.

TABLE 1

| | Thermal Conductivity |
|---|---|
| MATERIAL | W/m*° K |
| Aluminum | 167 |
| beryllium oxide | 265 |
| aluminum nitride | 180 |
| silicon carbide | 70 |
| boron nitride | 60 |
| aluminum oxide | 20 |

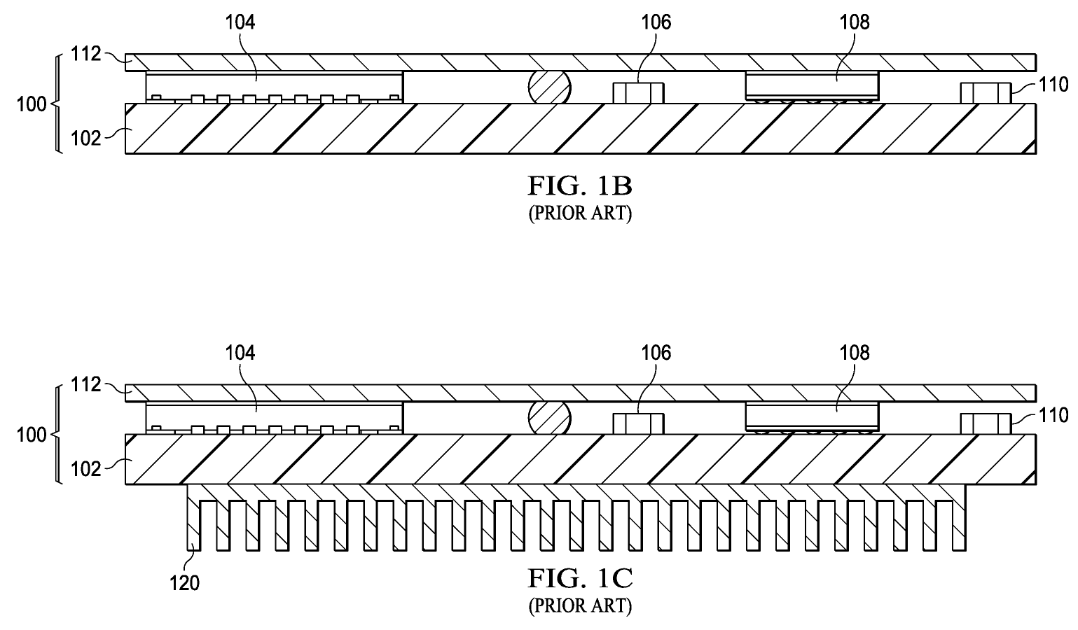

The low-attenuating heat spreader may be manufactured with a variety of designs. Illustrative example designs are portrayed in FIGS. 2A, 2B, and 2C.

FIG. 2A illustrates a flat panel low-attenuating heat spreader 200 design. FIG. 2B illustrates a parallel fin low-attenuating heat spreader 202. FIG. 2C illustrates a parallel pillar array 294 low-attenuating heat spreader. Other low-attenuating heat spreader structures may also be designed.

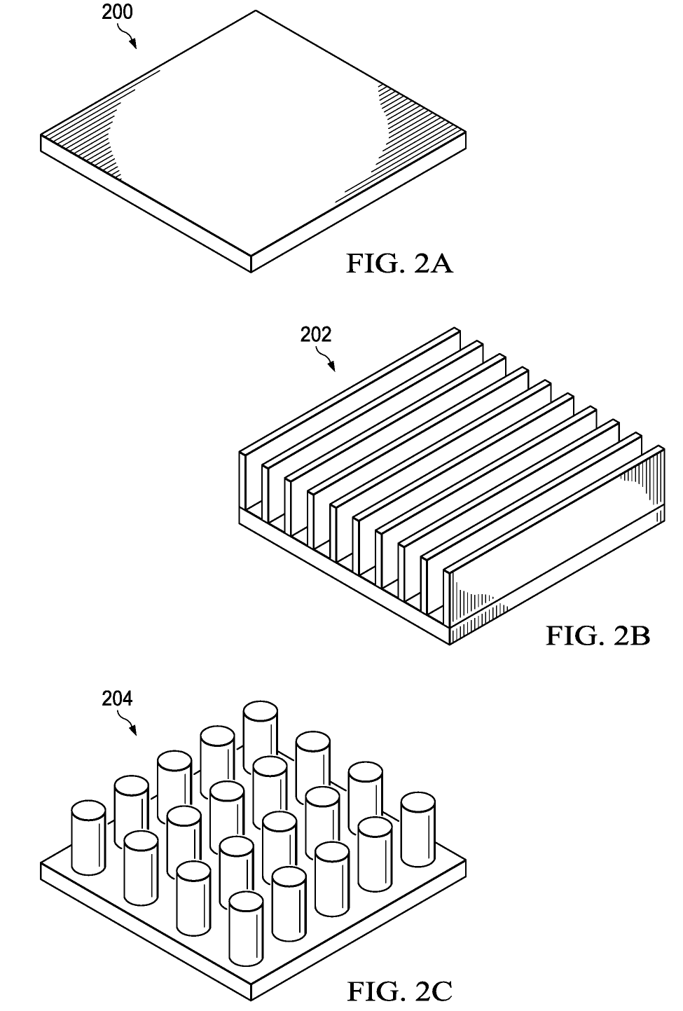

The low-attenuating heat spreaders 200, 202, and 204 may be bonded to an antenna array 112 as shown in FIG. 3A, 3B, and 3C to form heat dissipating antennas 300, 302, and 304. One method of bonding the low-attenuating heat spreaders to the antenna array 112 is using a thermally conductive epoxy. The heat dissipating antennas, 300, 302, and 304, broadcast and detect high frequency signals with high gain and also effectively dissipate heat from the high frequency integrated circuits to which the heat dissipating antenna is coupled.

TABLE 2

| | gain (dB) |
|---|---|
| ANTENNA | at 33 GHz |
| 16 × 16 antenna array with no heat spreader | 16 |
| 16 × 16 array with flat panel heat spreader (FIG. 3A) | 15.4 |
| 16 × 16 array with parallel plate-fin heat spreader (FIG. 3B) | 15.4 |

Table 2 shows the impact low-attenuating heat spreaders 112 have on the antenna gain of a 16×16 antenna array. The material of the low-attenuating heat spreaders in Table 2 is aluminum nitride. As shown in Table 2 the low-attenuating heat spreaders reduce antenna gain by a few percent in contrast to the conventional metallic heat spreader which reduces antenna gain by more than 50%.

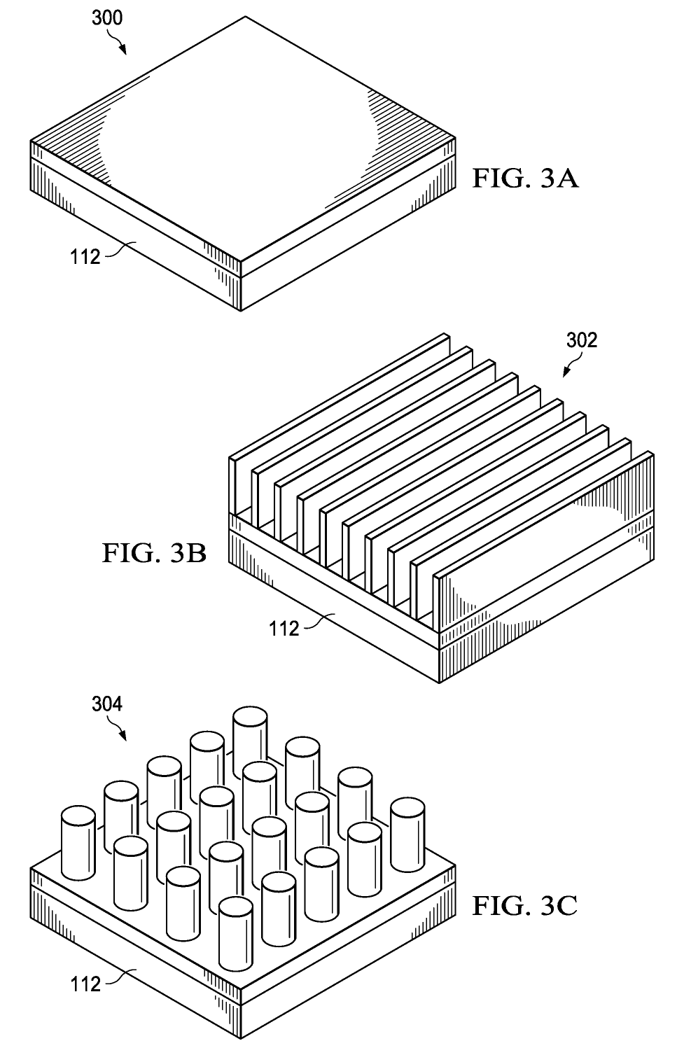

As shown in FIG. 4 heat dissipating antenna 302 may be coupled to a high frequency integrated circuit 100 such as a baseband, radio frequency, and power amplifiers integrated circuit. The embodiment heat dissipating antenna 302 significantly improves heat removal from the underlying integrated circuit 100.

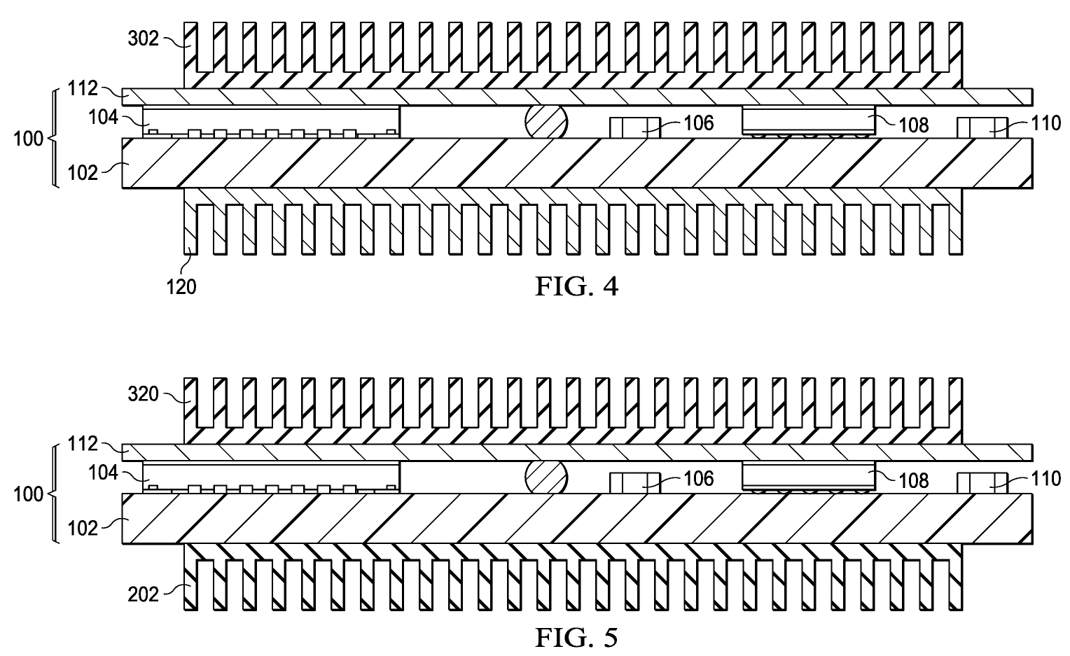

As is illustrated in FIG. 5 a low-attenuating heat spreader 202 may also bonded to the substrate 102 for enhanced heat dissipation. In some applications, it may be advantageous for the heat spreader that is attached to the substrate 102 to be non-metallic and low-attenuating.

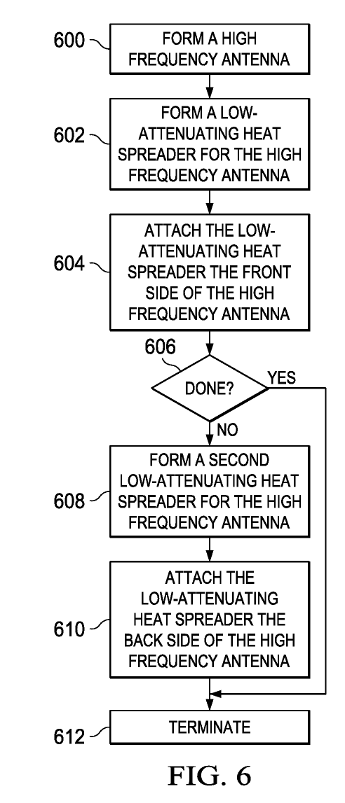

FIG. 6 is a flow chart illustrating a method for forming a high frequency antenna with a low-attenuating heat spreader.

In step 600 a high-frequency antenna is provided.

In step 602 a low-attenuating heat spreader is formed of a dielectric material with high thermal conductivity such as aluminum nitride, barium oxide, and silicon carbide.

In step 604 the low-attenuating heat spreader is coupled to the front side of the high frequency antenna using a thermally conductive bonding agent such as a thermally conductive epoxy for example.

In step 606 a decision is made if a low-attenuating heat spreader is to be coupled to the front side of the high frequency antenna only or if a low-attenuating heat spreader is also to be coupled to the backside. If a low-attenuating heat spreader is to be coupled to the front side only the flow chart proceeds to step 612 and terminates.

If, however, a second low-attenuating heat spreader is to be coupled to the backside of the high frequency antenna, the flow chart proceeds to step 608 to form a second low-attenuating heat spreader and then to step 610 to attach the second low-attenuating heat spreader to the backside of the high frequency antenna before terminating in step 612.

While various embodiments of the present invention have been described above, it should be understood that they have been presented by way of example only and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

1-20. (canceled)

21. An apparatus comprising:
a substrate;
at least one integrated circuit attached to the substrate;
an antenna attached to the at least one integrated circuit; and
a first heat spreader attached to the antenna.

22. The apparatus of claim 21 further comprising a second heat spreader attached to the substrate.

23. The apparatus of claim 21 further comprising at least one electrical component attached to the substrate.

24. The apparatus of claim 21, wherein the first heat spreader is attached to the antenna using a heat conductive epoxy.

25. The apparatus of claim 21, wherein the first heat spreader is a parallel plate heat spreader.

26. The apparatus of claim 21, wherein the first heat spreader is a flat plate heat spreader.

27. The apparatus of claim 21, wherein the first heat spreader is a parallel pillar heat spreader.

28. The apparatus of claim 21, wherein the first heat spreader is composed of dielectric material.

29. The apparatus of claim 28, wherein the dielectric material is one of aluminum nitride, beryllium oxide, aluminum oxide, silicon carbide, and boron nitride.

30. The apparatus of claim 21, wherein the at least one integrated circuit is one of a radio frequency chip and a baseband chip.

31. The apparatus of claim 22, wherein the second heat spreader is one of a parallel plate heat spreader, a flat plate heat spreader, and a parallel pillar heat spreader.

32. The apparatus of claim 22, wherein the second heat spreader is composed of dielectric material.

33. An apparatus comprising:
a substrate;
at least one integrated circuit attached to the substrate; and
an antenna structure attached to the at least one integrated circuit, the antenna structure comprising:
an antenna; and
a first heat spreader electrically connected to the antenna.

34. The apparatus of claim 33 further comprising a second heat spreader attached to the substrate.

35. The apparatus of claim 33 further comprising at least one electrical component attached to the substrate.

36. The apparatus of claim 33, wherein the first heat spreader is composed of dielectric material.

37. The apparatus of claim 36, wherein the dielectric material is one of aluminum nitride, beryllium oxide, aluminum oxide, silicon carbide, and boron nitride.

38. The apparatus of claim 33, wherein the antenna structure comprises an array of antennas.

39. An apparatus comprising:
a substrate;
at least one integrated circuit attached to the substrate;
an antenna attached to the at least one integrated circuit; and
a first heat spreader directly attached to the antenna using a conductive epoxy.

40. The apparatus of claim 39 further comprising a second heat spreader attached to the substrate.
